(19) United States
(12) Patent Application Publication
(10) Pub. No.: US 2005/0202624 A1
(43) Pub. Date: Sep. 15, 2005

(54) Plasma ion implantation system

(75) Inventor: Hong-Jyh Li, Austin, TX (US)

Correspondence Address: Dicke, Billig & Czaja, PLLC;Suite 2250, Fifth Street Towers, 100 South Fifth Street, Minneapolis, MN, 55402, US

(73) Assignee: Infineon Technologies North America Corp.

(21) Appl. No.: 10/816,503

(22) Filed: Apr. 1, 2004

Related U.S. Application Data
(63) Continuation-in-part of application No. 10/799,910, filed on Mar. 12, 2004.

(51) Int. Cl. H01L 21/8238

(52) U.S. Cl. 438/232

(57) ABSTRACT

A plasma ion implantation system comprises a vacuum chamber, a plasma generator configured to generate ions in the vacuum chamber, a sample holder inside the vacuum chamber, and a voltage source configured to provide a bias voltage between the sample holder and the vacuum chamber to attract ions to implant in a high-k dielectric layer of a sample positioned on the sample holder.

### CROSS-REFERENCE TO RELATED APPLICATIONS

This application is a continuation in part of U.S. patent application Ser. No. 10/799,910, entitled “ION IMPLANTATION OF HIGH-K MATERIALS IN SEMICONDUCTOR DEVICES,” filed Mar. 12, 2004, and is incorporated herein by reference.

### BACKGROUND

As metal-oxide semiconductor field effect transistor (MOSFET) devices continue to advance, the thickness of the gate dielectric continues to decrease to maintain the desired control of the MOSFET devices. According to the International Technology Roadmap for Semiconductors (ITRS), an equivalent oxide thickness (EOT) of less than 15 Å is necessary to meet the requirement of sub-100 nm MOSFET devices. Using conventional SiO₂ as the gate material, it is difficult to keep scaling the thickness below 20 Å without having high tunneling leakage current through the gate. Thus, various other gate dielectric materials having a higher dielectric constant (k) than SiO₂ have been studied extensively. These materials are known as high-k materials. SiO₂ has a k value of 3.9 while the various other gate dielectric materials being studied have k values in the range of 10 to 40.

The thickness of the gate dielectric required to control a MOSFET depends on the capacitance of the film. High-k material films and the thicknesses that would result may be compared to other high-k materials and SiO₂ using equivalent oxide thickness (EOT). For example, a high-k film with a k value of 20 may be about five times thicker than a SiO₂ film and still have the same control over a MOSFET. The thicker gate dielectric layer may reduce tunneling leakage current through the gate, enabling sub-100 nm MOSFET devices.

### SUMMARY

One embodiment of the invention provides a plasma ion implantation system. The plasma ion implantation system comprises a vacuum chamber, a plasma generator configured to generate ions in the vacuum chamber, a sample holder inside the vacuum chamber, and a voltage source configured to provide a bias voltage between the sample holder and the vacuum chamber to attract ions to implant in a high-k dielectric layer of a sample positioned on the sample holder.

### BRIEF DESCRIPTION OF THE DRAWINGS

Embodiments of the invention are better understood with reference to the following drawings. The elements of the drawings are not necessarily to scale relative to each other. Like reference numerals designate corresponding similar parts.

FIG. 1 is a diagram illustrating a cross-section of one embodiment of a metal-oxide semiconductor field effect transistor (MOSFET) cell, according to the present invention.

FIG. 2 is a diagram illustrating a cross-section of one embodiment of a photoresist layer, a nitride layer, an oxide layer, and a substrate.

FIG. 3 is a diagram illustrating a cross-section of one embodiment of a substrate including isolation regions.

FIG. 4 is a diagram illustrating a cross-section of one embodiment of a substrate with isolation regions and a pre-gate material layer.

FIG. 5a is a diagram illustrating a cross-section of one embodiment of a substrate with isolation regions, a pre-gate material layer, and a high-k dielectric layer.

FIG. 5b is a diagram illustrating a cross-section of one embodiment of a substrate with isolation regions, pre-gate material layer, high-k dielectric layer, and buffer layer.

FIG. 5c is a diagram illustrating a cross-section of one embodiment of a substrate with isolation regions, pre-gate material layer, and a stacked high-k dielectric layer.

FIG. 6a is a diagram illustrating one embodiment of implantation of a species into a cross-section of a high-k dielectric layer.

FIG. 6b is a diagram illustrating one embodiment of implantation of a species into a cross-section of a buffer layer and a high-k dielectric layer.

FIG. 7 is a diagram illustrating a cross-section of one embodiment of a substrate with isolation regions, pre-gate material layer, high-k dielectric layer, buffer layer, and gate electrode layer.

FIG. 8 is a diagram illustrating a cross-section of one embodiment of a substrate with isolation regions, pre-gate material layer, high-k dielectric layer, buffer layer, and gate electrode layer after etching.

FIG. 9 is a diagram illustrating one embodiment of implantation of a cross-section of the silicon substrate layer to form source and drain extension regions.

FIG. 10 is a diagram illustrating a cross-section of one embodiment of an oxide layer on a substrate with isolation regions, pre-gate material layer, high-k dielectric layer, buffer layer, and gate electrode layer.

FIG. 11 is a diagram illustrating a cross-section of one embodiment of an oxide layer on a substrate with isolation regions, pre-gate material layer, high-k dielectric layer, buffer layer, and gate electrode layer after etching the oxide layer to form spacers.

FIG. 12 is a diagram illustrating implantation of a cross-section of the silicon substrate to form source and drain regions.

FIG. 13a is a graph illustrating one embodiment of a pulsed gate voltage (Vg) versus drain current (Id) measurement for HfO₂.

FIG. 13b is a graph illustrating one embodiment of a pulsed Vg versus Id measurement for HfON.

FIG. 14 is a two graphs illustrating one embodiment of electron mobility and hole mobility for HfON and HfO₂.

FIG. 15 is two graphs illustrating one embodiment of gate leakage current (Jg) reduction in NMOS and PMOS transistors.

FIG. 16 is a graph illustrating one embodiment of the PMOS Id versus Vg characteristics of HfON and HfO₂.

FIG. 17 is a graph illustrating one embodiment of time dependent dielectric breakdown (TDDB) for HfON and HfO₂.

FIG. 18 is a diagram illustrating one embodiment of a plasma ion implantation system.

### DETAILED DESCRIPTION

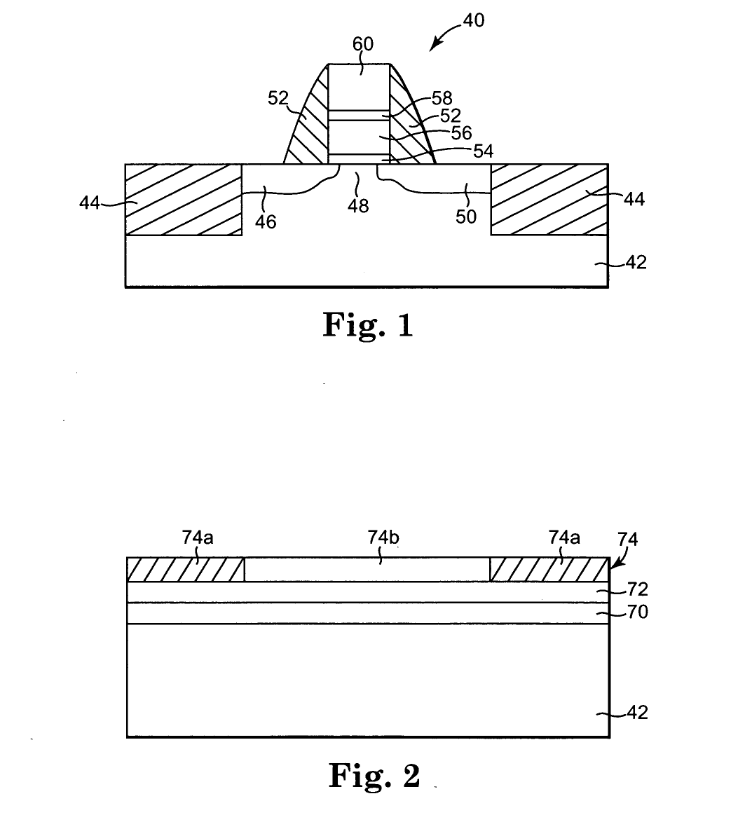

FIG. 1 is a diagram illustrating a cross-section of one embodiment of a metal-oxide semiconductor field effect transistor (MOSFET) cell 40, according to the present invention. Transistor cell 40 is one of a plurality of transistor cells in a MOSFET device. Transistor cell 40 includes substrate 42, isolation regions 44, source 46, channel 48, and drain 50. Transistor cell 40 also includes pre-gate material layer 54, high-k dielectric layer 56, buffer layer 58, gate electrode 60, and spacers 52. In the present invention, high-k dielectric layer 56 is implanted with a species for improved performance characteristics of the layer.

Substrate 42 is a silicon substrate or other suitable substrate. Isolation regions 44 are trenches etched into substrate 42 that have been filled with an insulating material, such as SiO₂ or other suitable insulator with a dielectric constant less than four, to insulate transistor cell 40 from adjacent transistor cells. Source 46 and drain 50 are doped, for example, with arsenic, phosphorous, boron or other suitable material, depending upon the desired transistor characteristics, using a self-aligning ion implantation process in substrate 42 or other suitable process. Channel 48 is between source 46 and drain 50.

Pre-gate material layer 54 is centered over channel 48 and can include SiO₂, SiON, or other suitable material based upon the type of pre-gate treatment performed on substrate 42. In one embodiment, a pre-gate treatment that results in no pre-gate material layer 54 is used. In that case, high-k dielectric layer 56 is in direct contact with substrate 42.

High-k dielectric layer 56 is deposited on pre-gate material layer 54 and can include HfO₂, HfSiOₓ, Al₂O₃, ZrO₂, ZrSiOₓ, SiO₂, SiON, Ta₂O₅, La₂O₃, or other suitable high-k material. High-k dielectric layer 56 provides the gate dielectric for transistor cell 40. High-k dielectric layer 56 is implanted with a species, such as N, F, Si, O, Hf, Zr, Ti, Ta, Y, V, Sc, Ba, Sr, Ru, B, Al, Ga, In, Ge, C, P, As, Sb, La, or other suitable species to reduce impurity diffusion, increase crystallization temperature, improve thermal stability, etc. of high-k dielectric layer 56.

In one embodiment, optional buffer layer 58 is deposited on high-k dielectric layer 56 and can include TiN, HfN, TaN, ZrN, LaN, SiN, TiSi, full poly salicidation using materials of Ni, Ti, or Co, or other suitable material. Buffer layer 58 provides a buffer during implantation of high-k dielectric layer 56. In addition, during implantation of high-k dielectric layer 56, buffer layer 58 provides a diffusion reservoir of which the species in the layer can diffuse into the underneath high-k dielectric layer 56 to further improve the high-k quality of high-k dielectric layer 56. For example, if TiN is used for buffer layer 58 and N is used as the implant species, then both Ti and N can diffuse into high-k dielectric layer 56 and improve the permittivity (due to Ti) and the reliability (due to N) of high-k dielectric layer 56.

Gate electrode layer 60 is deposited on buffer layer 58 and can include aluminum, polysilicon, or other suitable conductive material. In one embodiment, where buffer layer 58 is not used, gate electrode layer 60 is deposited directly on high-k dielectric layer 56. Gate electrode layer 60 provides the gate electrode for transistor cell 40.

Spacers 52 are deposited on the sides of gate electrode layer 60, buffer layer 58, high-k dielectric layer 56, pre-gate material layer 54, and substrate 42 and can include SiO₂, Si₃N₄, TEOS or other suitable dielectric material. Spacers 52 isolate gate electrode 60, buffer layer 58, high-k dielectric layer 56, and pre-gate material layer 54 from source 46 and drain 50.

Using a high-k material implanted with a species to improve the high-k quality for the gate dielectric provides an equivalent oxide thickness (EOT) that allows increased performance and reduced transistor size while not increasing tunneling leakage current through the gate. Tunneling leakage current through the gate is kept to a desired level as high-k materials implanted with a species improve control over MOSFET devices. The improved control comes without reducing the thickness of the gate dielectric, as required if using SiO₂ for the gate dielectric.

Of the high-k materials, HfO₂ films are compatible with both polysilicon and metal gate electrodes. HfO₂, however, has a low immunity to oxygen and boron diffusion. Incorporating N or another suitable species into HfO₂ films reduces impurity diffusion, increases crystallization temperature, improves thermal stability, etc. To incorporate N into HfO₂ films, ion implantation is used to dope high-k dielectric layer 56 and optional buffer layer 58.

FIGS. 2-10 are diagrams illustrating an exemplary process for fabricating one embodiment of transistor cell 40. In the exemplary process, transistor cell 40 is fabricated from substrate 42, pre-gate material layer 54, high-k dielectric layer 56, buffer layer 58, gate electrode 60, and spacers 52.

FIG. 2 is a diagram illustrating a cross-section of one embodiment of a photoresist layer 74, a nitride layer 72, an oxide layer 70, and substrate 42. Isolation regions 44 can be formed using a shallow trench isolation (STI) process. Oxide layer 70 is formed on substrate 42. Nitride layer 72 is formed on oxide layer 70 and photoresist layer 74 is formed on nitride layer 72.

Oxide layer 70 is grown or deposited on silicon substrate layer 42. Nitride layer 72 is deposited on oxide layer 70 using chemical vapor deposition (CVD) or other suitable deposition method. Photoresist layer 74 is spin-coated on nitride layer 72. A mask is used to expose portions 74a of photoresist layer 74 and prevent portions 74b of photoresist layer 74 from being exposed. Photoresist layer 74 is exposed to high intensity ultra-violet (UV) light through the mask to expose portions 74a of photoresist layer 74. Portions 74a of photoresist layer 74 define where isolation regions 44 will be formed in substrate 42.

The exposed portions 74a of photoresist are removed to leave unexposed portions 74b of photoresist on nitride layer 72. The newly exposed nitride layer 72 portions, the oxide layer 70 portions beneath the newly exposed nitride layer 72 portions, and portions of substrate 42 beneath the newly exposed nitride layer 72 portions are etched away using wet etching, dry etching, or other suitable etching process. After etching, the newly formed trenches are filled with oxide using chemical vapor deposition (CVD) or other suitable deposition technique.

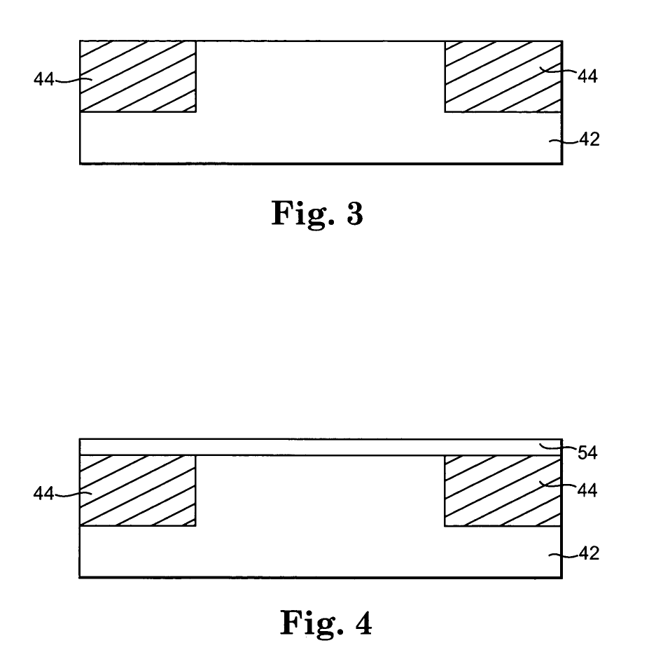

FIG. 3 is a diagram illustrating a cross-section of one embodiment of silicon substrate 42 with isolation regions 44 formed in the substrate from the etching process previously described and illustrated in FIG. 2. In addition, the remaining nitride layer 72 and oxide layer 70 are removed from substrate 42. Depending upon the desired characteristics for the MOSFET device, substrate 42 can be implanted to form n-wells and/or p-wells and Vₜₙ and/or Vₜₚ adjust implants can be performed.

FIG. 4 is a diagram illustrating a cross-section of one embodiment of substrate 42 with isolation regions 44 and a pre-gate material layer 54. A pre-gate treatment is used to clean and treat the surface of substrate 42. The pre-gate treatment leaves a pre-gate material layer including SiO₂, SiON, or other material based upon the pre-gate treatment used. Pre-gate material layer 54 has a thickness in the range of 2 Å to 10 Å, such as 5 Å. Pre-gate material layer 54 is annealed at a temperature between 0° C. and 800° C., for between 0 s and 60 s. In one embodiment, the pre-gate treatment of substrate 42 does not leave a pre-gate material layer 54 on substrate 42.

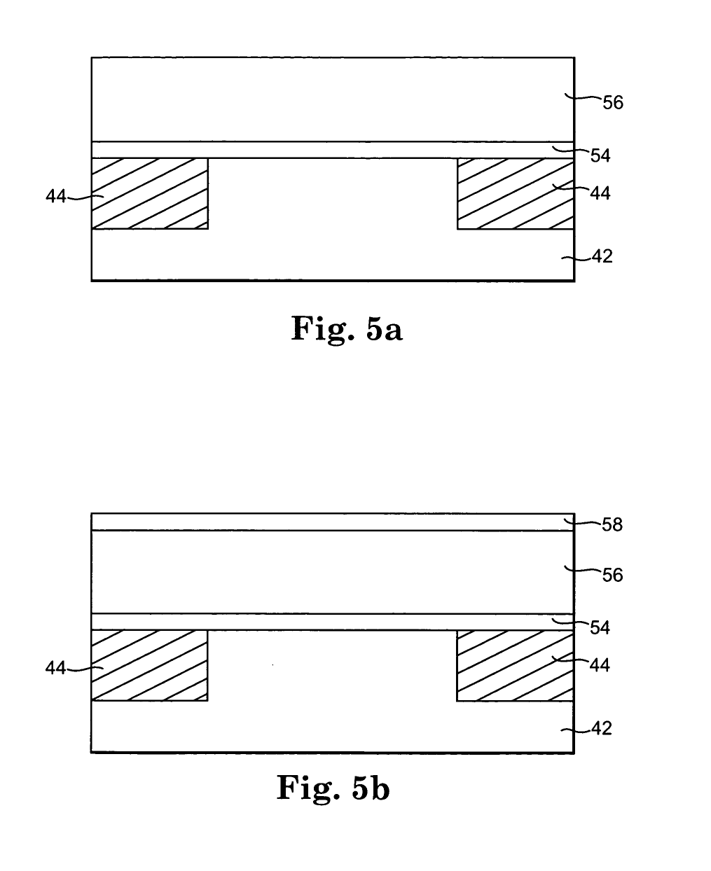

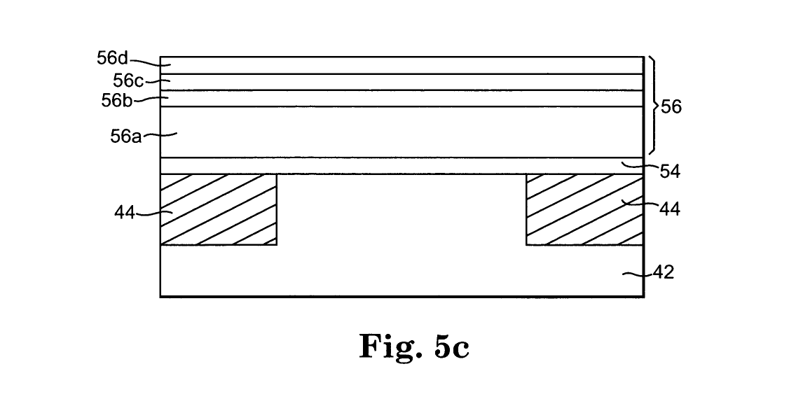

FIG. 5a is a diagram illustrating a cross-section of one embodiment of substrate 42 with isolation regions 44, pre-gate material layer 54, and high-k dielectric layer 56. High-k dielectric layer 56 can include HfO₂, HfSiOₓ, Al₂O₃, ZrO₂, ZrSiOₓ, SiO₂, SiON, Ta₂O₅, La₂O₃, or other suitable high-k dielectric material. In one embodiment, one or more of these materials can be included in high-k layer 56 in different combinations or in stacked layers. High-k dielectric layer 56 is deposited on pre-gate material layer 54 using atomic layer deposition (ALD), metal organic chemical vapor deposition (MOCVD), plasma vapor deposition (PVD), jet vapor deposition (JVP), or other suitable deposition technique. High-k dielectric layer 56 has a thickness within the range of 10 Å to 60 Å, such as 30 Å, and an EOT within the range of 3 Å to 20 Å. In one embodiment, high-k dielectric layer 56 has an EOT of 16 Å for a low power transistor cell 40 or an EOT of 5 Å for a high performance transistor cell 40. In one embodiment, where the pre-gate treatment leaves no pre-gate material layer 54, high-k dielectric layer 56 is deposited directly on substrate 42.

FIG. 5b is a diagram illustrating a cross-section of one embodiment of substrate 42 with isolation regions 44, pre-gate material layer 54, high-k dielectric layer 56, and optional buffer layer 58. Buffer layer 58 can include TiN, HfN, TaN, ZrN, LaN, SiN, TiSi, full poly salicidation using Ni, Ti, or Co, or other suitable material. Buffer layer 58 is deposited on high-k dielectric layer 56 using ALD, MOCVD, PVD, JVP, or other suitable deposition technique. Buffer layer 58 has a thickness in the range of 10 Å to 200 Å, such as 20 Å. In one embodiment, buffer layer 58 includes a stack of layers, with each layer including TiN, HfN, TaN, ZrN, LaN, SiN, TiSi, full poly salicidation using materials of Ni, Ti, or Co, or other suitable material.

FIG. 5c is a diagram illustrating a cross-section of one embodiment of substrate 42 with isolation regions 44, pre-gate material layer 54, and a stacked high-k dielectric layer 56. In this embodiment, high-k dielectric layer 56 includes a base high-k dielectric layer 56a and high-k dielectric layers 56b, 56c, and 56d. In other embodiments, a different number of high-k dielectric layers are used. Base high-k dielectric layer 56a is deposited on pre-gate material layer 54. High-k dielectric layer 56b is deposited on base high-k dielectric layer 56a. High-k dielectric layer 56c is deposited on high-k dielectric layer 56b. High-k dielectric layer 56d is deposited on high-k dielectric layer 56c.

Each high-k dielectric layer 56a-56d can include HfO₂, HfSiOₓ, Al₂O₃, ZrO₂, ZrSiOₓ, SiO₂, SiON, Ta₂O₅, La₂O₃, or other suitable high-k dielectric material. In one embodiment, base high-k dielectric layer 56a comprises HfSiOₓ, ZrSiOₓ, and each high-k dielectric layer 56b-56d comprises one of HfO₂, Al₂O₃, ZrO₂, SiO₂, SiON, Ta₂O₅, and La₂O₃. Each high-k dielectric layer 56a-56d is deposited using ALD, MOCVD, PVD, JVP, or other suitable deposition technique. The combined thickness of high-k dielectric layers 56a-56d is within the range of 10 Å to 60 Å, such as 30 Å, and an EOT within the range of 3 Å to 20 Å. Each layer 56a-56d can be implanted with a different species.

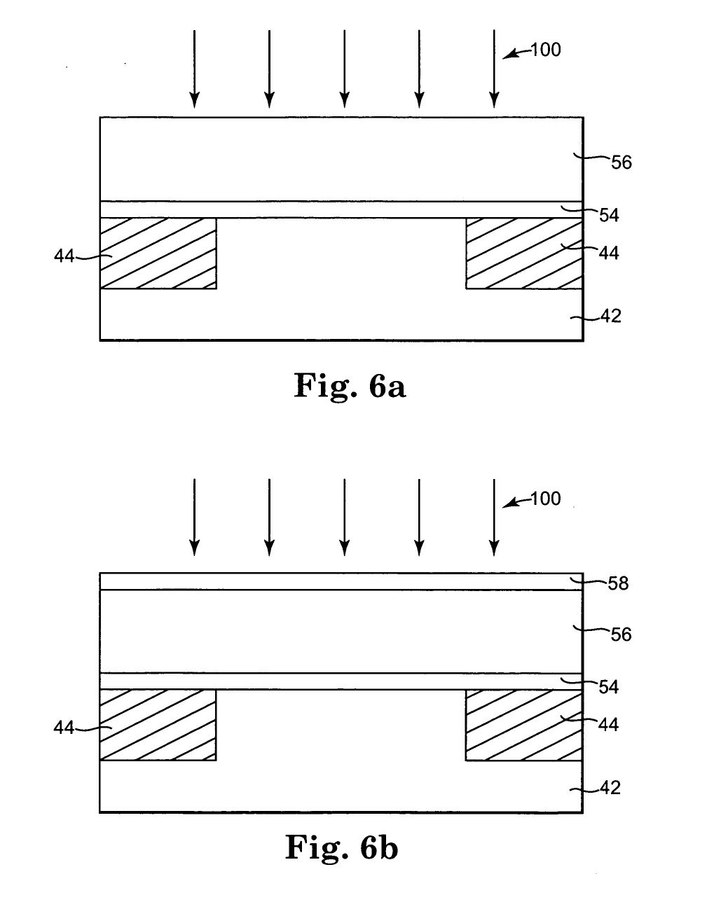

FIG. 6a is a diagram illustrating a cross-section of one embodiment of ion implantation 100 of high-k dielectric layer 56 without buffer layer 58. High-k dielectric layer 56 is implanted with one or more species including N, N2, F, F2, Si, O, O2, Hf, Zr, Ti, Ta, Y, V, Sc, BA, Sr, Ru, B, Al, Ga, In, Ge, C, P, As, Sb, La, their molecular or cluster forms, or other suitable species. The species are implanted using a beamline implanter, plasma implanter, or other suitable implanter. The species are implanted using an energy range between 5 eV to 10 keV, such as 100 eV. The dose of ion implantation is within the range of 1×10¹³ ions/cm² to 1×10¹⁶ ions/cm², such as 2×10¹⁴ ions/cm². With implantation complete, high-k dielectric layer 56 is annealed at a temperature between 200° C. and 1000° C., for between 0 s and 120 s.

FIG. 6b is a diagram illustrating a cross-section of one embodiment of ion implantation 100 of both buffer layer 58 and high-k dielectric layer 56. Buffer layer 58 and high-k dielectric layer 56 are implanted with one or more species including N, N2, F, F2, Si, O, O2, Hf, Zr, Ti, Ta, Y, V, Sc, BA, Sr, Ru, B, Al, Ga, In, Ge, C, P, As, Sb, La, their molecular or cluster forms, or other suitable species. The species are implanted using a beamline implanter, plasma implanter, or other suitable implanter. The species are implanted using an energy range between 5 eV to 10 keV, such as 100 eV. The dose of ion implantation is within the range of 1×10¹³ to 1×10¹⁶ ions/cm², such as 2×10¹⁴ ions/cm². With implantation complete, high-k dielectric layer 56 is annealed at a temperature between 200° C. and 1000° C., for between 0 s and 120 s. Buffer layer 58 is annealed at a temperature between 0° C. and 1000° C., for between 0 s and 60 s.

Use of buffer layer 58 allows for more effective control of species to be confined in high-k dielectric layer 56. In addition, buffer layer 58 can act as a diffusion reservoir of which the species in the layer can diffuse into high-k dielectric layer 56 and further improve the high-k quality of high-k dielectric layer 56. For example, if TiN is used as buffer layer 58 and N as the implant species, both Ti and N can diffuse into high-k dielectric layer 56 and improve the permeativity (due to Ti), and reliability (due to N) of high-k dielectric layer 56.

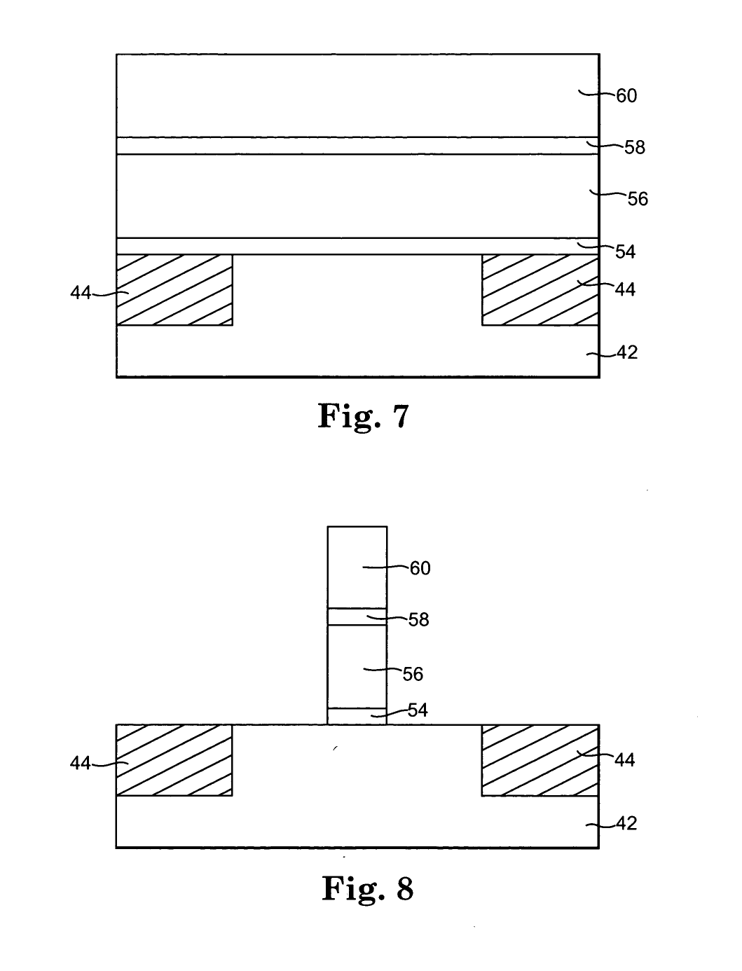

FIG. 7 is a diagram illustrating a cross-section of one embodiment of substrate 42 with isolation regions 44, pre-gate material layer 54, high-k dielectric layer 56, optional buffer layer 58, and gate electrode layer 60. Gate electrode layer 60 comprises aluminum, polysilicon, or other suitable conductive material. Gate electrode layer 60 is deposited on buffer layer 58 using CVD or other suitable deposition technique. In one embodiment, where buffer layer 58 is not used, gate electrode layer 60 is deposited directly on high-k dielectric layer 56.

FIG. 8 is a diagram illustrating a cross-section of one embodiment of substrate 42 with isolation regions 44, pre-gate material layer 54, high-k dielectric layer 56, optional buffer layer 58, and gate electrode layer 60 after portions of gate electrode layer 60, buffer layer 58, high-k dielectric layer 56 and pre-gate material layer 54 have been etched away. A photoresist and etching process is used to remove the unwanted portions.

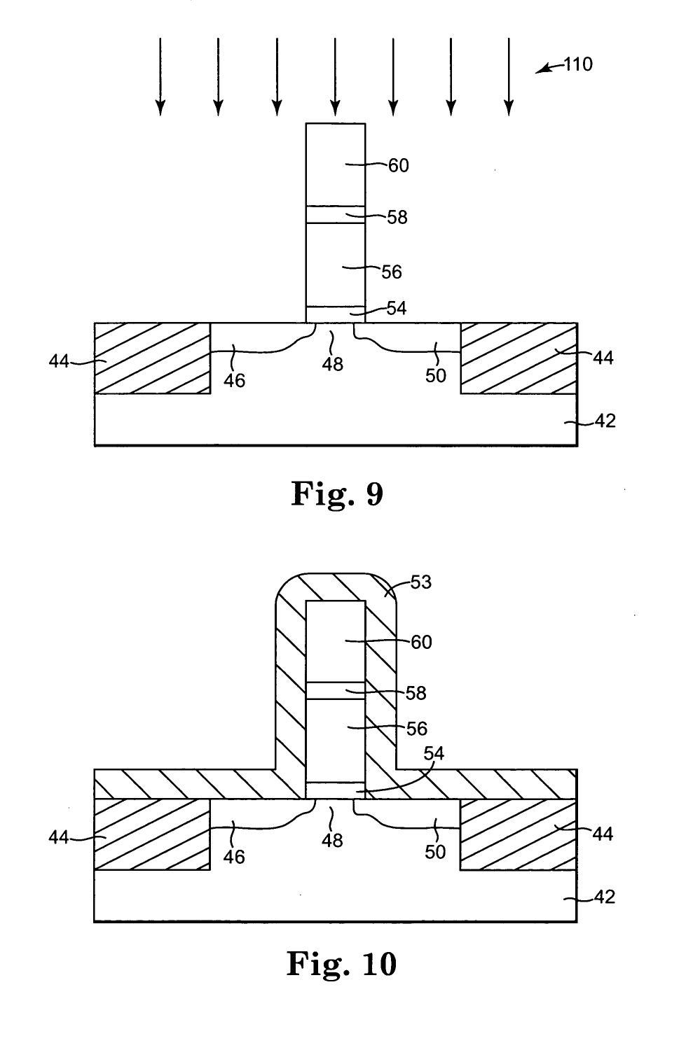

FIG. 9 is a diagram illustrating a cross-section of one embodiment of ion implantation 10 in a self-aligned process to form source extension region 46 and drain extension region 50. Substrate 42 is implanted with a species to form source extension region 46 and drain extension region 50. The implant species can include arsenic, phosphorous, boron, or other suitable species based upon the desired characteristics of transistor cell 40, such as whether transistor cell 40 is PMOS or NMOS.

FIG. 10 is a diagram illustrating a cross-section of one embodiment of substrate 42 with isolation regions 44, pre-gate material layer 54, high-k dielectric layer 56, optional buffer layer 58, gate electrode layer 60, and oxide layer 53. Oxide layer 53 is deposited on gate electrode layer 60, the sides of buffer layer 58, high-k dielectric layer 56, and pre-gate material layer 54, and on substrate 42. Oxide layer 53 includes SiO₂ or other suitable material. Oxide layer 53 is deposited using CVD or other suitable deposition technique.

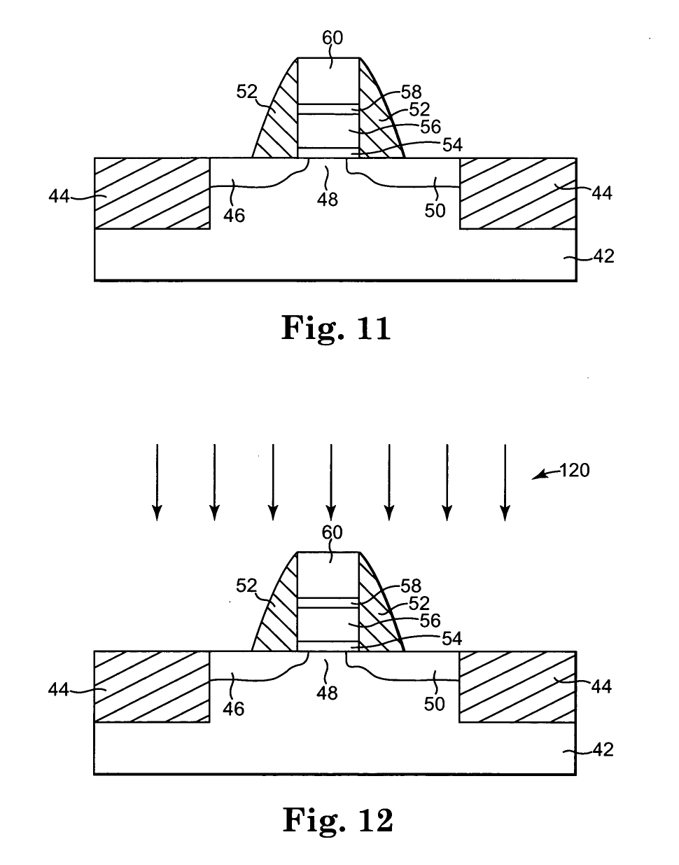

FIG. 11 is a diagram illustrating a cross-section of one embodiment of substrate 42 with isolation regions 44, pre-gate material layer 54, high-k dielectric layer 56, optional buffer layer 58, gate electrode layer 60, and oxide layer 53 after etching to form spacers 52. A photoresist and etching process is used to remove unwanted portions of oxide layer 53 to form spacers 52.

FIG. 12 is a diagram illustrating one embodiment of ion implantation 120 of a cross-section of substrate 42 to form source 46 and drain 50. Substrate 42 is implanted with a species to form source 46 and drain 50. The implant species can include arsenic, phosphorous, boron, or other suitable species based upon the desired characteristics of transistor cell 40, such as whether transistor cell 40 is a PMOS transistor cell or an NMOS transistor cell.

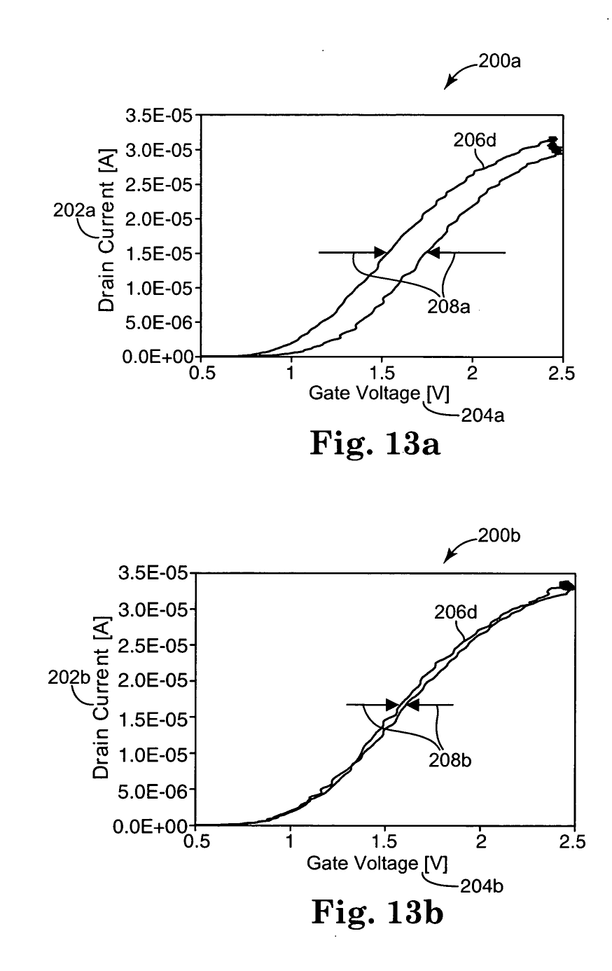

FIGS. 13a-17 illustrate comparisons of performance characteristics between embodiments of transistor cell 40 where HfO₂ is used as the high-k dielectric layer 56 material. FIGS. 13a-17 illustrate performance characteristic comparisons between a high-k dielectric layer 56 that has not been ion implanted (remaining HfO₂) and a high-k dielectric layer 56 that has been ion implanted with N (becoming HfON). For this embodiment, HfO₂ is deposited on an HF—O₃ cleaned Si surface by an ALD process at 300° C. and N₂ ion implantation is done with 200 eV and 2×10¹⁴ ion/cm² dose. Post implantation anneal is done in N₂ at 700° C. for 10 s. TiN is deposited on top of the high-k dielectric layer using CVD to a thickness of 100 Å. Polysilicon is then deposited on top of the TiN layer using CVD to a thickness of 1800Å. A rapid thermal annealing (RTA) in N₂ at 1000° C. for 10 s is used to activate the source, drain, and polysilicon dopants. An HfO₂ control split without N₂ implant is included as the reference.

FIG. 13a is a graph 200a illustrating one embodiment of pulsed gate voltage (Vg) 204a versus drain current (Id) 202a for HfO₂ films. Curve 206a illustrates measurements for a non-implanted HfO₂ high-k gate dielectric transistor. Y-axis, Id 202A, varies from 0 A to 3.5×10⁻⁵ A and x-axis, Vg 204a, varies from 0.5V to 2.5V. The measurements 206a are taken using a gate voltage varying between −1V to 2.5V having a pulse width of 100 μs and a rise time and fall time of 5 μs. At 50% of Id max at 208a, the change in the threshold voltage (Vt) equals 205 mV. The EOT equals 13.9 Å.

FIG. 13b is a graph 200b illustrating one embodiment of pulsed Vg 204b versus Id 202b for HfON films. Curve 206b illustrates measurements for an implanted HfON high-k gate dielectric transistor. Y-axis, Id 202b, varies from 0 A to 3.5×10⁻⁵ A and x-axis, Vg 204b, varies from 0V to 2.5V. The measurements 206b are taken using a gate voltage varying between −1V to 2.5V having a pulse width of 100 μs and a rise time and fall time of 5 μs. At 50% of Id max at 208b, the change in Vt equals 17 mV. The EOT equals 12.7 ÅA. Comparing the measurement at 208a for the non-implanted HfO₂ high-k dielectric to the measurement at 208b for the implanted HfON high-k gate dielectric illustrates an order of magnitude improvement in electrical stability of the HfON gate dielectric as compared to the HfO₂ gate dielectric.

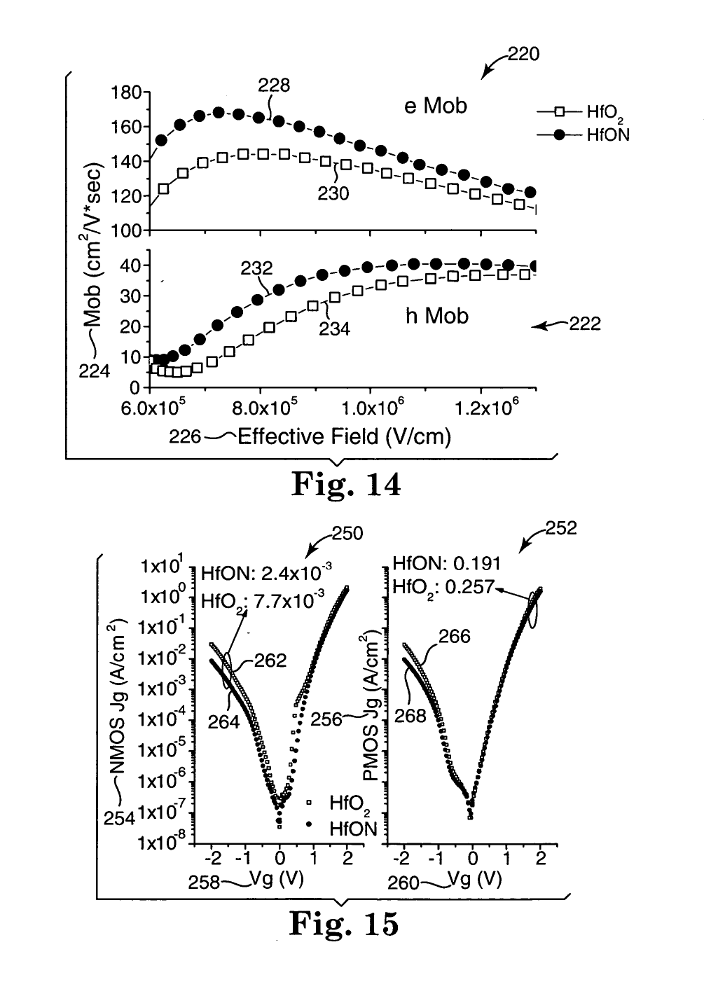

FIG. 14 is a graph 220 illustrating one embodiment of mobility of electrons for both HfON and HfO₂ films and a graph 222 illustrating one embodiment of mobility of holes for both HfON and HfO₂ films. Graph 220 and graph 222 illustrate mobility extraction for NMOS and PMOS. The x-axis, effective field 226, varies from 6.0×10⁵ V/cm to 1.3×10⁶ V/cm and the y-axis, mobility (MOB) varies from 0 cm² /V*sec to 40 cm²/V*sec for graph 222 and from 100 cm²/V*sec to 180 cm²/V*sec for graph 220. Electron mobility values for HfON are indicated by curve 228 and electron mobility values for HfO₂ are indicated by curve 230. Hole mobility values for HfON are indicated by curve 232 and hole mobility values for HfO₂ are indicated by curve 234. As illustrated in the graphs, the mobility for electrons and holes for the HfON film perform better than those for the HfO₂ film.

FIG. 15 is two graphs 250 and 252 illustrating embodiments of the gate current (Ig) versus gate voltage (Vg) characteristics for HfON film and HfO₂ film devices. Graph 250 illustrates measurements for an NMOS device and graph 252 illustrates measurements for a PMOS device. The x-axis, Vg 258, of NMOS graph 250 ranges from −2V to 2V and the y-axis, NMOS leakage current (Jg) 254, ranges from 1×10⁻⁸ A/cm² to 1×10¹ A/cm². The x-axis, Vg 260, of PMOS graph 252 ranges from −2V to 2V and the y-axis, PMOS Jg 254, ranges from 1×10⁸ A/cm² to 1×10¹ A/cm². For NMOS graph 250, curve 262 indicates measurements for HfO₂ and curve 264 indicates measurements for HfON. For PMOS graph 252, curve 266 indicates measurements for HfO₂ and curve 268 indicates measurements for HfON. Although HfON shows approximately 1 Å less EOT than HfO₂, HfON has less gate leakage current than HfO₂. The gate leakage current reduction evaluated at flat band voltage (Vfb)−1 is 69% for NMOS and at Vfb+1 is 25% for PMOS.

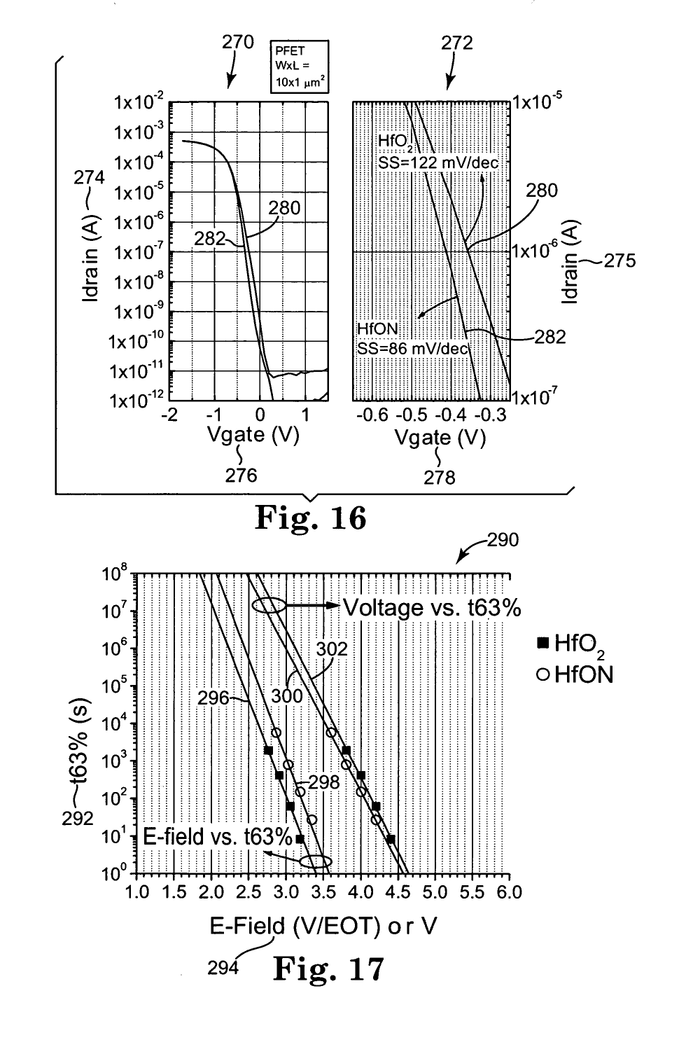

FIG. 16 is two graphs 270 and 272 illustrating one embodiment of the PMOS Id versus Vg characteristics of HfON and HfO₂. Graph 272 illustrates a portion of graph 270 in more detail. The x-axis, Vg 276, of graph 270 varies from −2V to 1V and the y-axis, Id 274, varies from 1×10⁻² A to 1×10² A. The x-axis, Vg 278, of graph 272 varies from −0.6V to −0.3V and the y-axis, Id 275 varies from 1×10⁷ A to 1×10⁵ A. Curve 280 indicates the measurements for HfO₂ and curve 282 indicates the measurements for HfON. The subthreshold slope (SS) taken between −0.3V to −0.4V equals 122 mV/dec for HfO₂ and 86 mV/dec for HfON. PMOS subthreshold slope shows improvement for HfON over HfO₂, whereas in NMOS, SS of those films are comparable (not shown).

FIG. 17 is a graph 290 illustrating one embodiment of time dependent dielectric breakdown (TDDB) of HfON and HfO₂ films. The TDDB results are for approximately 60 to 70 devices under test (DUTs) per data point. The x-axis, electric field (E-field) or Voltage 294, varies from 1.0V/EOT or V to 6.0V/EOT or V and the y-axis, time at which 63% of units fail (t63%) 292, varies from 10⁰ s to 10⁸s. For E-field vs. t63%, curve 296 indicates measurements for HfO₂ and curve 298 indicates measurements for HfON. For Voltage vs. t63%, curve 300 indicates measurements for HfON and curve 302 indicates measurements for HfO₂. As illustrated in graph 290, the HfON film performs better than the HfO₂ film in terms of E-field.

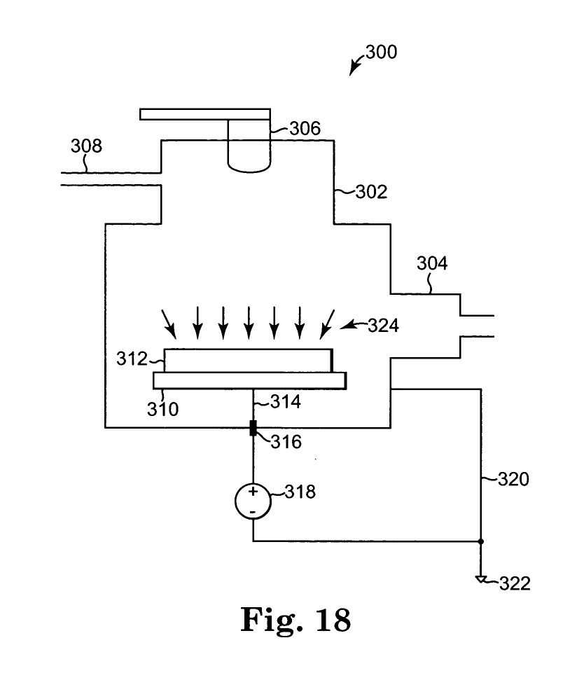

FIG. 18 is a diagram illustrating one embodiment of a plasma ion implantation system 300 suitable for implanting ions in high-k dielectric layer 56 and buffer layer 58. Plasma ion implantation system 300 includes vacuum chamber 302, plasma generator 306, vacuum pump 304, gas feed system 308, sample holder 310, and voltage source 318. Vacuum chamber 302 is electrically coupled to ground 322 through conductor 320. Sample holder 310 is electrically coupled to voltage source 318 through conductor 314. Vacuum chamber 302 includes an isolation region 316 where conductor 314 passes through the wall of vacuum chamber 302. Voltage source 318 is electrically coupled to ground 322 through conductor 320. Vacuum pump 304, gas feed system 308, and plasma generator 306 are coupled to vacuum chamber 302.

Sample 312 is positioned on sample holder 310. Sample 312 is any suitable sample in which ions are to be implanted, such as a sample including high-k dielectric layer 56 and optional buffer layer 58.

Vacuum pump 304 sets the pressure in vacuum chamber 302 to a specified value. Gas feed system 308 provides a gas to vacuum chamber 302. Plasma generator 306 generates ions from the gas. The species of the ions generated can include N, F, Si, O, Hf, Zr, Ti, Ta, Y, V, Sc, Ba, Sr, Ru, B, Al, Ga, In, Ge, C, P, As, and Sb, their molecular or cluster forms, or other suitable species.

Voltage source 318 provides a bias voltage between sample holder 310 and vacuum chamber 302. The bias voltage accelerates the ions toward sample 312, as indicated at 324, to implant the ions in the sample. In one embodiment, the ions are implanted in a high-k dielectric layer 56 of sample 312. In another embodiment, the ions are implanted in a buffer layer 58 of sample 312. The ions are implanted with an implant energy within the range of 5 eV to 10 keV and the dose of implantation is within the range of 1×10¹³ ions/cm² to 1×10¹⁶ ions/cm².

In one embodiment, voltage source 318 is a DC voltage source. Biasing sample 312 with a DC voltage source repels negative ions and electrons from sample 312 and attracts positive ions toward sample 312 to implant the positive ions in sample 312.

1. A plasma ion implantation system comprising:
a vacuum chamber;
a plasma generator configured to generate ions in the vacuum chamber;
a sample holder inside the vacuum chamber; and
a voltage source configured to provide a bias voltage between the sample holder and the vacuum chamber to attract ions to implant in a high-k dielectric layer of a sample positioned on the sample holder.

2. The plasma ion implantation system of claim 1, wherein the ions comprise N.

3. The plasma ion implantation system of claim 1, wherein the ions comprise one of F, Si, O, Hf, Zr, Ti, Ta, Y, V, Sc, Ba, Sr, Ru, B, Al, Ga, In, Ge, C, P, As, and Sb.

4. The plasma ion implantation system of claim 1, wherein the voltage source comprises a DC voltage source.

5. The plasma ion implantation system of claim 1, wherein the voltage source comprises an AC voltage source.

6. The plasma ion implantation system of claim 1, further comprising:
a vacuum pump for providing a specified pressure in the vacuum chamber.

7. The plasma ion implantation system of claim 1, further comprising:
a gas feed system for providing a gas to the vacuum chamber from which the plasma generator generates the ions.

8. A plasma ion implantation system comprising:
a vacuum chamber;
a vacuum pump configured to set a pressure in the vacuum chamber;
a gas feed system configured to provide a gas to the vacuum chamber;
a plasma generator configured to generate ions from the gas;
a sample holder configured to hold a sample to be implanted; and
a DC voltage source configured to accelerate positive ions toward a high-k dielectric layer of the sample to implant the ions in the high-k dielectric layer.

9. The plasma ion implantation system of claim 8, wherein the DC voltage source is coupled to the sample holder and the vacuum chamber.

10. The plasma ion implantation system of claim 8, wherein the ions comprise N.

11. The plasma ion implantation system of claim 8, wherein the ions comprise one of F, Si, O, Hf, Zr, Ti, Ta, Y, V, Sc, Ba, Sr, Ru, B, Al, Ga, In, Ge, C, P, As, and Sb.

12. The plasma ion implantation system of claim 8, wherein the high-k dielectric layer comprises one of HfO₂, HfSiO, ZrO₂, ZrSiO, SiO₂, SiON, Ta₂O₅, La₂O₃, and AL₂O₃.

13. The plasma ion implantation system of claim 8, wherein the sample comprises a buffer layer proximate the high-k dielectric layer.

14. The plasma ion implantation system of claim 13, wherein the DC voltage source is configured to accelerate positive ions toward the buffer layer of the sample to implant the ions in the buffer layer.

15. The plasma ion implantation system of claim 14, wherein the buffer layer comprises one of TiN, HfN, TaN, ZrN, LaN, SiN, and TiSi.

16. A plasma ion implantation system comprising:
a vacuum chamber;
a vacuum pump configured to set a pressure in the vacuum chamber;
a gas feed system configured to provide a gas to the vacuum chamber;
a plasma generator configured to generate ions from the gas, the ions comprising one of F, Si, O, Hf, Zr, Ti, Ta, Y, V, Sc, Ba, Sr, Ru, B, Al, Ga, In, Ge, C, P, As, and Sb;
a sample holder configured to hold a sample to be implanted; and
a voltage source configured to accelerate positive ions toward a first high-k dielectric layer of the sample to implant the ions in the first high-k dielectric layer.

17. The plasma ion implantation system of claim 16, wherein the voltage source is configured to accelerate positive ions toward a second high-k dielectric layer of the sample adjacent the first high-k dielectric layer to implant the ions in the second high-k dielectric layer.

18. The plasma ion implantation system of claim 17, wherein the first high-k dielectric layer comprises one of HfSiOₓ and ZrSiOₓ.

19. The plasma ion implantation system of claim 18, wherein the second high-k dielectric layer comprises one of HfO₂, HfSiOₓ, ZrO₂, ZrSiOₓ, SiO₂, SiON, Ta₂O₅, La₂O₃, and AL₂O₃.

20. The plasma ion implantation system of claim 19, wherein the voltage source is configured to accelerate positive ions toward a buffer layer of the sample adjacent the second high-k dielectric layer to implant the ions in the buffer layer.

21. The plasma ion implantation system of claim 20, wherein the buffer layer comprises at least one of TiN, HfN, TaN, ZrN, LaN, SiN, and TiSi.

22. The plasma ion implantation system of claim 20, wherein the buffer layer comprises a stack of layers.

23. The plasma ion implantation system of claim 21, wherein the voltage source is a DC voltage source.

24. The plasma ion implantation system of claim 21, wherein the voltage source is an AC voltage source.

25. A method of implanting ions in a sample, the method comprising:
positioning a sample comprising a high-k dielectric layer on a sample holder in a vacuum chamber;
providing a gas to the vacuum chamber;
setting a pressure in the vacuum chamber;
generating a plasma in the vacuum chamber from the gas; and
accelerating ions in the plasma toward the sample to implant the ions in the high-k dielectric layer.

26. The method of claim 25, wherein generating a plasma comprises generating a plasma comprising N ions.

27. The method of claim 25, wherein generating a plasma comprises generating a plasma comprising one of F, Si, O, Hf, Zr, Ti, Ta, Y, V, Sc, Ba, Sr, Ru, B, Al, Ga, In, Ge, C, P, As, and Sb ions.

28. The method of claim 25, wherein accelerating ions in the plasma toward the sample comprises biasing the sample with a DC voltage.

29. The method of claim 25 wherein accelerating ions in the plasma toward the sample comprises biasing the sample with an AC voltage.

30. The method of claim 25, wherein accelerating ions in the plasma toward the sample to implant the ions in the sample comprises implanting the ions having a dose within a range of 1×10¹³ ions/cm² to 1×10¹⁶ ions/cm².

31. The method of claim 25, wherein accelerating ions in the plasma toward the sample to implant the ions in the sample comprises accelerating the ions to have an implant energy within a range of 5 eV to 10 keV.
